(19) United States
(12) Patent Application Publication
(10) Pub. No.: US 2025/0062227 A1
(43) Pub. Date: Feb. 20, 2025

(54) Gradually Changed Dummy Pattern Distribution Around TSVs

(71) Applicant: Taiwan Semiconductor Manufacturing Co., Ltd., Hsinchu (TW)

(72) Inventors: Kuo-Yen Liu, Hsinchu (TW); Chao Yi Lin, Kaohsiung City (TW)

(21) Appl. No.: 18/517,577

(22) Filed: Nov. 22, 2023

Related U.S. Application Data
(60) Provisional application No. 63/532,446, filed on Aug. 14, 2023.

(51) Int. Cl. H01L 23/528; H01L 23/498; H01L 23/522

(52) U.S. Cl. CPC H01L 23/5283; H01L 23/49816; H01L 23/49822; H01L 23/5226

(57) ABSTRACT

A method includes forming an integrated circuit device on a semiconductor substrate, forming a through-via penetrating through the semiconductor substrate, and forming dummy patterns surrounding the through-via. The dummy patterns include a first plurality of dummy patterns having a first pattern density, and a second plurality of dummy patterns. The first plurality of dummy patterns are between the through-via and the second plurality of dummy patterns. The second plurality of dummy patterns have a second pattern density different from the first pattern density.

### PRIORITY CLAIM AND CROSS-REFERENCE

This application claims the benefit of the following provisionally filed U.S. Patent application: Application No. 63/532,446, filed on Aug. 14, 2023, and entitled “Dummy Patterns Around TSV to Reduce Wafer/Chip Warpage,” which application is hereby incorporated herein by reference.

### BACKGROUND

Through-Silicon Vias (TSVs) are used as electrical paths in device dies, so that the conductive features on opposite sides of the device dies may be interconnected. The formation process of a TSV may include etching a semiconductor substrate to form an opening, filling the opening with a conductive material to form the TSV, performing a backside grinding process to remove a portion of the semiconductor substrate from backside and to expose the TSV, and forming an electrical connector on the backside of the semiconductor substrate to connect to the TSV.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate the cross-sectional views of intermediate stages in the formation of dies including through-silicon-vias (TSVs) using a via-middle process in accordance with some embodiments.

FIGS. 11-14 illustrate the cross-sectional views of intermediate stages in the formation of dies including TSVs using a via-last process in accordance with some embodiments.

FIG. 15 illustrates TSVs and dummy pattern regions around the TSVs in accordance with some embodiments.

FIGS. 16 and 17 illustrate the distribution of dummy patterns around a TSV in accordance with some embodiments.

FIGS. 18-20 illustrate the possible dummy patterns in accordance with some embodiments.

FIG. 21 illustrates the staggered dummy patterns in a plurality of metal layers in accordance with some embodiments.

FIG. 22 illustrates the dummy patterns in two metal layers have lengthwise directions perpendicular to each other in accordance with some embodiments.

FIG. 23 illustrates a process flow for designing dummy patterns in accordance with some embodiments.

FIG. 24 illustrates a process flow for forming a device die including TSVs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Through-Silicon-Vias (TSVs, also referred to as through-vias), dummy patterns surround the TSVs, and the method of forming the same are provided. In accordance with some embodiments, the dummy patterns surrounding a TSV have different pattern densities, with the regions closer to the TSV having lower pattern densities than the regions farther away from the TSV. With the different pattern densities, the warpage of respective device die and wafer may be reduced. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

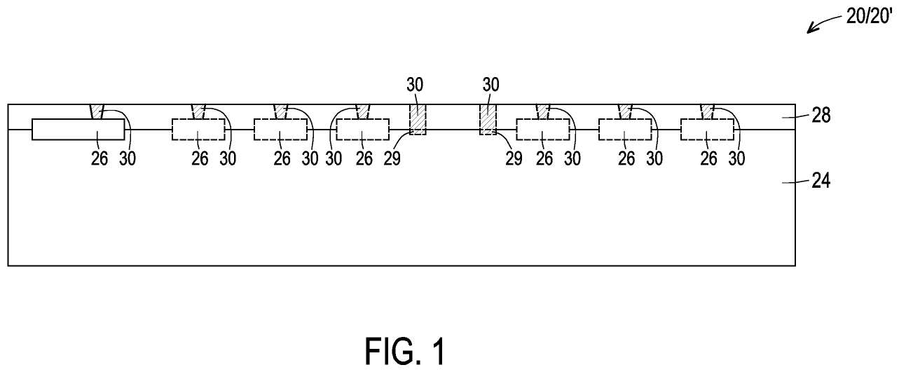

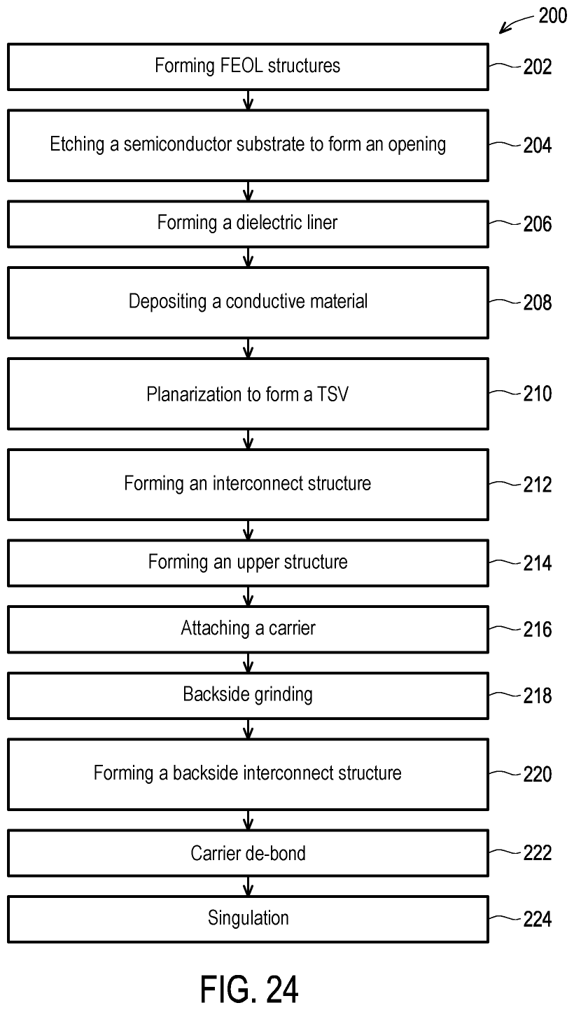

FIGS. 1-10 illustrate the cross-sectional views of intermediate stages in the formation of a die including through-vias in accordance with some embodiments. The corresponding processes are also reflected schematically in the process flow 200 as shown in FIG. 24.

FIG. 1 illustrates a cross-sectional view of wafer 20. In accordance with some embodiments, wafer 20 is or comprises a device wafer including active devices and possibly passive devices, which are represented as integrated circuit devices 26. Wafer 20 may include a plurality of chips/dies 20′ therein, with one of chips 20′ being illustrated. In accordance with alternative embodiments of the present disclosure, wafer 20 is an interposer wafer, which is free from active devices, and may or may not include passive devices.

In accordance with some embodiments, wafer 20 includes semiconductor substrate 24 and the features formed at a top surface of semiconductor substrate 24. Semiconductor substrate 24 may be formed of or comprise crystalline silicon, crystalline germanium, silicon germanium, carbon-doped silicon, or a III-V compound semiconductor such as GaAsP, AlInAs, AlGaAs, GaInAs, GaInP, GaInAsP, or the like. Shallow Trench Isolation (STI) regions (not shown) may be formed in semiconductor substrate 24 to isolate the active regions in semiconductor substrate 24.

In accordance with some embodiments, integrated circuit devices 26 are formed, and are collectively referred to as Front-end of line structures. The respective process is illustrated as process 202 in the process flow 200 as shown in FIG. 24. Integrated circuit devices 26 may include Complementary Metal-Oxide Semiconductor (CMOS) transistors, resistors, capacitors, diodes, and the like in accordance with some embodiments. The details of integrated circuit devices 26 are not illustrated herein. In accordance with alternative embodiments, wafer 20 is used for forming interposers, which are free from active devices and passive devices.

Inter-Layer Dielectric (ILD) 28 is formed over semiconductor substrate 24 and fills the spaces between the gate stacks of transistors (not shown) in integrated circuit devices 26. In accordance with some embodiments, ILD 28 is formed of silicon oxide, Phospho Silicate Glass (PSG), Boro Silicate Glass (BSG), Boron-doped Phospho Silicate Glass (BPSG), Fluorine-doped Silicate Glass (FSG), or the like. ILD 28 may be formed using spin coating, Flowable Chemical Vapor Deposition (FCVD), or the like. In accordance with some embodiments, ILD 28 may also be formed using a deposition method such as Plasma Enhanced Chemical Vapor Deposition (PECVD), Low Pressure Chemical Vapor Deposition (LPCVD), or the like.

Contact plugs 30 are formed in ILD 28, and are used to electrically connect integrated circuit devices 26 to overlying metal lines and vias. In accordance with some embodiments, contact plugs 30 are formed of or comprise a conductive material selected from tungsten, aluminum, copper, titanium, tantalum, titanium nitride, tantalum nitride, alloys therefore, and/or multi-layers thereof. The formation of contact plugs 30 may include forming contact openings in ILD 28, filling a conductive material(s) into the contact openings, and performing a planarization process (such as a Chemical Mechanical Polish (CMP) process or a mechanical grinding process) to level the top surfaces of contact plugs 30 with the top surface of ILD 28.

In accordance with some embodiments, some silicide regions 29 are formed underlying some contact regions 30. The illustrated silicide regions 29 and the overlying contact regions 30, when viewed from top, form rings. The silicide region 29 and the overlying contact plug 30 may be used for electrically connecting the guard ring of the subsequently formed TSV to semiconductor substrate 24 in accordance with some embodiments. The subsequently formed guard ring may also be electrically connected to electrical ground in accordance with some embodiments.

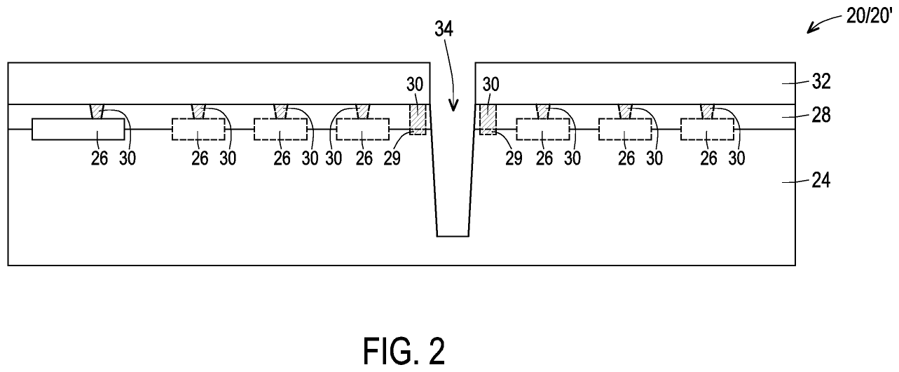

Referring to FIG. 2, etching mask 32 is formed and patterned. In accordance with some embodiments, etching mask 32 comprises photoresist, and may or may not include a hard mask formed of TiN, BN, or the like. An anisotropic etching process is then performed to form opening 34 penetrating through ILD 28. Semiconductor substrate 24 is further etched so that opening 34 extends to an intermediate level of semiconductor substrate 24, wherein the intermediate level is between the top surface and the bottom surface of semiconductor substrate 24. Opening 34 is used for forming a TSV, and hence is referred to as TSV opening 34 hereinafter. The respective process is illustrated as process 204 in the process flow 200 as shown in FIG. 24. Etching mask 32 is then removed.

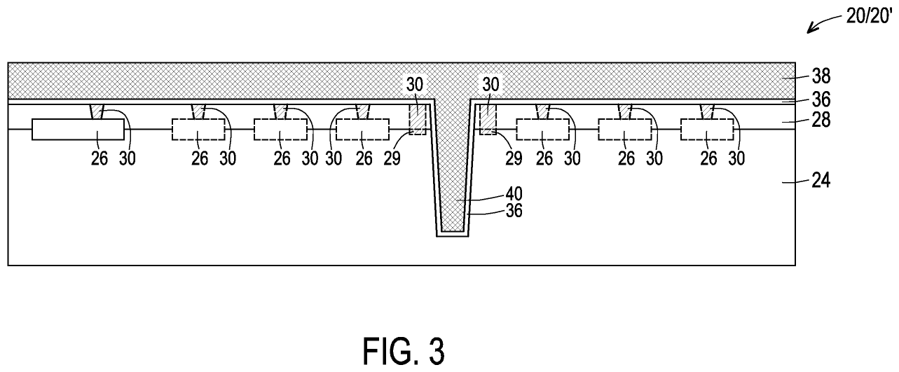

Referring to FIG. 3, dielectric liner 36 is formed, for example, through a deposition process. The respective process is illustrated as process 206 in the process flow 200 as shown in FIG. 24. Dielectric liner 36 may include horizontal portions outside of TSV opening 34, and vertical portions extending into TSV opening 34. In accordance with some embodiments, dielectric liner 36 is formed of or comprises a dielectric material such as silicon oxide, silicon nitride, silicon carbide, silicon oxynitride, silicon oxycarbide, or the like, or combinations thereof. The deposition method may include Plasma Enhance Chemical Vapor Deposition (PECVD), Atomic Layer Deposition (ALD), Physical Vapor Deposition (PVD), or the like.

FIG. 3 further illustrates the deposition of a conductive material 38 on dielectric liner 36. The respective process is illustrated as process 208 in the process flow 200 as shown in FIG. 24. In accordance with some embodiments, conductive material 38 includes a metal seed layer, and a metallic material over the metal seed layer. In accordance with some embodiments, the metal seed layer is formed through Physical Vapor Deposition (PVD). The metal seed layer may be a single layer, for example, formed of copper, or may include a plurality of layers, for example, including a conductive barrier layer and a copper layer on the conductive barrier layer. The conductive barrier layer may be formed of or comprise TIN, Ti, TaN, Ta, or the like.

The metallic material may include copper, a copper alloy, tungsten, or the like. The deposition process may be performed using electrochemical plating (ECP), electro-less plating, or the like. The plating is performed until the top surface of the plated the metallic material is higher than the top surface of dielectric liner 36.

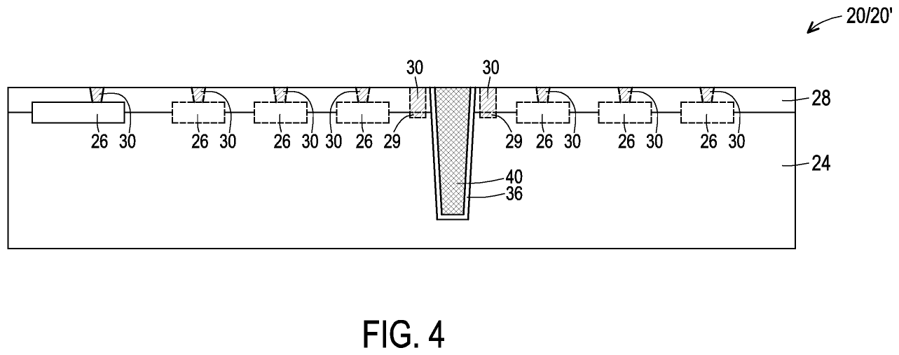

FIG. 4 illustrates a planarization process, which may be a CMP process or a mechanical grinding process, for planarizing the top surface of the metallic material 38 and dielectric liner 36. The respective process is illustrated as process 210 in the process flow 200 as shown in FIG. 24. In accordance with some embodiments, the planarization process is performed using ILD 28 as a stop layer. The remaining portions of the metal seed layer and the metallic material are collectively referred to as TSV 40 hereinafter.

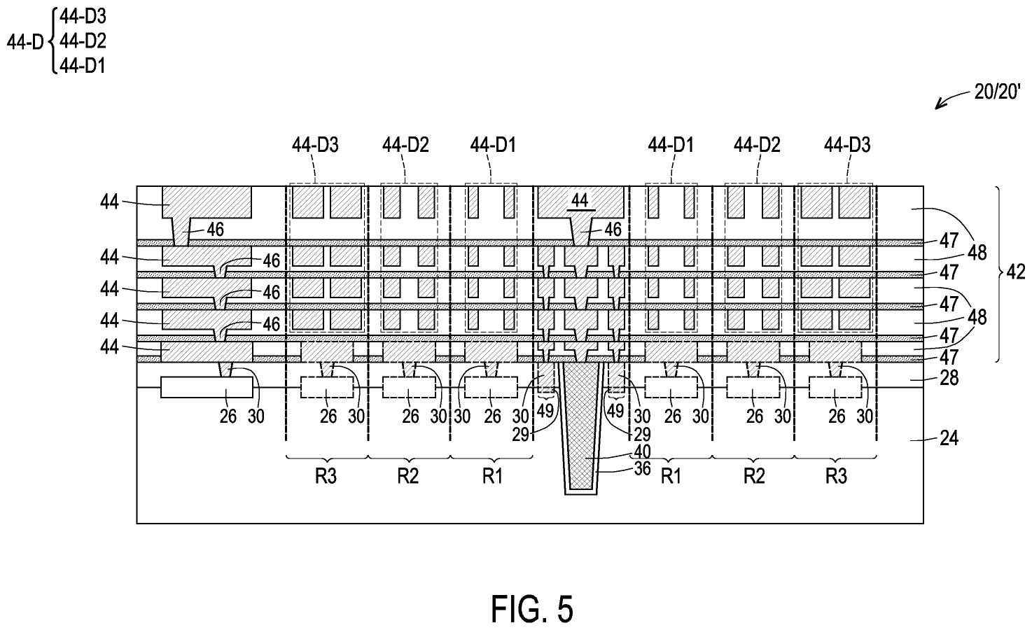

Referring to FIG. 5, interconnect structure 42 is formed. The respective process is illustrated as process 212 in the process flow 200 as shown in FIG. 24. Interconnect structure 42 includes metal lines 44 and vias 46, which are formed in dielectric layers 48 (also referred to as Inter-metal Dielectrics (IMDs)) and etch stop layers 47. The metal lines at a same level are collectively referred to as a metal layer hereinafter. In accordance with some embodiments, interconnect structure 42 includes a plurality of metal layers including metal lines 44 that are interconnected through vias 46.

Metal lines 44 and vias 46 may be formed of copper or copper alloys, and can also be formed of other metals. In accordance with some embodiments, dielectric layers 48 are formed of low-k dielectric materials. The dielectric constants (k values) of the low-k dielectric materials may be lower than about 3.5, for example. Dielectric layers 48 may comprise a carbon-containing low-k dielectric material, Hydrogen SilsesQuioxane (HSQ), MethylSilsesQuioxane (MSQ), or the like. Etch stop layers 47 may be formed of or comprise aluminum oxide, aluminum nitride, SiOC, SiON, or the like, or multi-layers thereof.

The formation of metal lines 44 and vias 46 in dielectric layers 48 may include single damascene processes and/or dual damascene processes. In a single damascene process for forming a metal line or a via, a trench or a via opening is first formed in one of dielectric layers 48, followed by filling the trench or the via opening with a conductive material. A planarization process such as a CMP process is then performed to remove the excess portions of the conductive material higher than the top surface of the dielectric layer, leaving a metal line or a via in the corresponding trench or via opening.

In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

In the same processes in which the metal layers in the interconnect structure 42 are formed, dummy patterns 44-D1, 44-2, and 44-D3 (collectively referred to as dummy patterns 44-D hereinafter) are also formed. Dummy patterns 44-D may be electrically floating. Guard ring 49 is also formed to encircle the region directly over TSV 40. Dummy patterns 44-D1, 44-2, and 44-D3 are formed in dummy pattern regions R1, R2, and R3, respectively, and may extend into the top metal layer of the interconnect structure 42, and may include portions in a plurality of metal layers. The details of dummy patterns 44-D1, 44-2, and 44-D3 are discussed subsequently.

In accordance with some embodiments, there may be integrated circuit devices 26 formed in dummy pattern regions R1, R2, and/or R3 and directly underlying the dummy patterns 44-D1, 44-2, and 44-D3. In accordance with alternative embodiments, no integrated circuit devices 26 are formed in dummy pattern regions R1, R2, and R3. Accordingly, the integrated circuit devices 26 in dummy pattern regions R1, R2, and R3 are illustrated as being dashed to indicate that they may be, or may not be, formed.

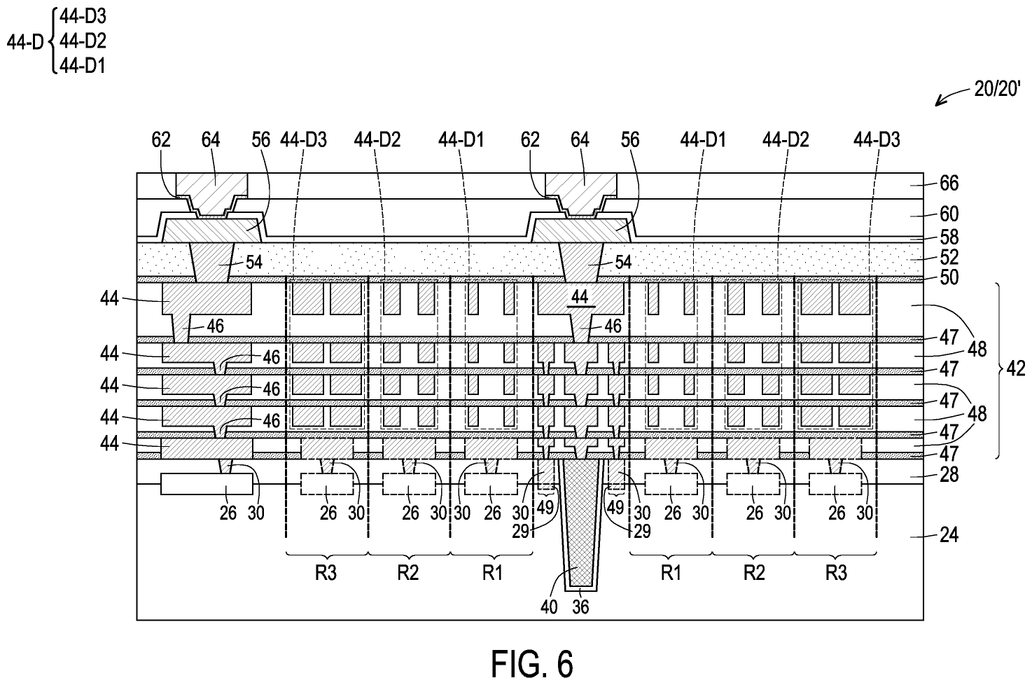

FIG. 6 illustrates the formation of an upper structure of wafer 20. The respective process is illustrated as process 214 in the process flow 200 as shown in FIG. 24. Etch stop layer 50 may be formed over interconnect structure 42. Passivation layer 52 (sometimes referred to as passivation-1 or pass-1) is formed over etch stop layer 50. In accordance with some embodiments, passivation layer 52 is formed of a non-low-k dielectric material having a dielectric constant equal to or greater than the dielectric constant of silicon oxide. Passivation layer 52 may be formed of or comprise an inorganic dielectric material, which may include a material selected from, and is not limited to, Undoped Silicate Glass (USG), silicon nitride (SiN), silicon oxide (SiO₂), silicon oxy-nitride (SiON), silicon oxy-carbide (SiOC), silicon carbide (SiC), or the like, combinations thereof, and/or multi-layers thereof. In accordance with some embodiments, the top surfaces of top dielectric layer 48 and metal lines 44 of the interconnect structure 42 are level with one another. Accordingly, passivation layer 52 may be a planar layer.

In accordance with some embodiments, vias 54 are formed in passivation layer 52 and etch stop layer 50 to electrically connect to the underlying top metal features 44. Metal pads 56 are further formed over vias 54. In accordance with some embodiments, metal pads 56 comprise aluminum, aluminum copper, or the like. Passivation layer 58 (sometimes referred to as passivation-2 or pass-2) is also formed, and may extend on the sidewalls and the top surfaces of metal pads 56. Passivation layer 58 may be formed of or comprises silicon oxide, silicon nitride, or the like, or multi-layers thereof.

In accordance with some embodiments, dielectric layer 60 is formed, for example, by dispensing a polymer in a flowable form, and then curing polymer layer 60. Dielectric layer 60 is patterned to expose metal pads 56. Dielectric layer 60, when formed of polymer, may be formed of or comprise polyimide, polybenzoxazole (PBO), or the like. Alternatively, dielectric layer 60 may be formed of or comprise an in organic dielectric material such as silicon oxide, silicon nitride, silicon oxynitride, or the like.

Under-Bump-Metallurgies (UBMs) 62 and bond pads 64 may be formed to electrically connect to the underlying metal pads 56. The formation processes of UBMs 62 and bond pads 64 may include forming openings in passivation layer 58 and polymer layer 60, depositing a blanket metal seed layer extending into the openings, forming a patterned plating mask on the metal seed layer, plating bond pads 64, removing the plating mask, and etching the portions of the blanket metal seed layer previously covered by the plating mask. In accordance with some embodiments, dielectric layer 66 is formed to have a top surface coplanar with the top surfaces of bond pads 64, and may be used for hybrid bonding. Other electrical connectors used for other bonding schemes such as solder bonding may also be formed.

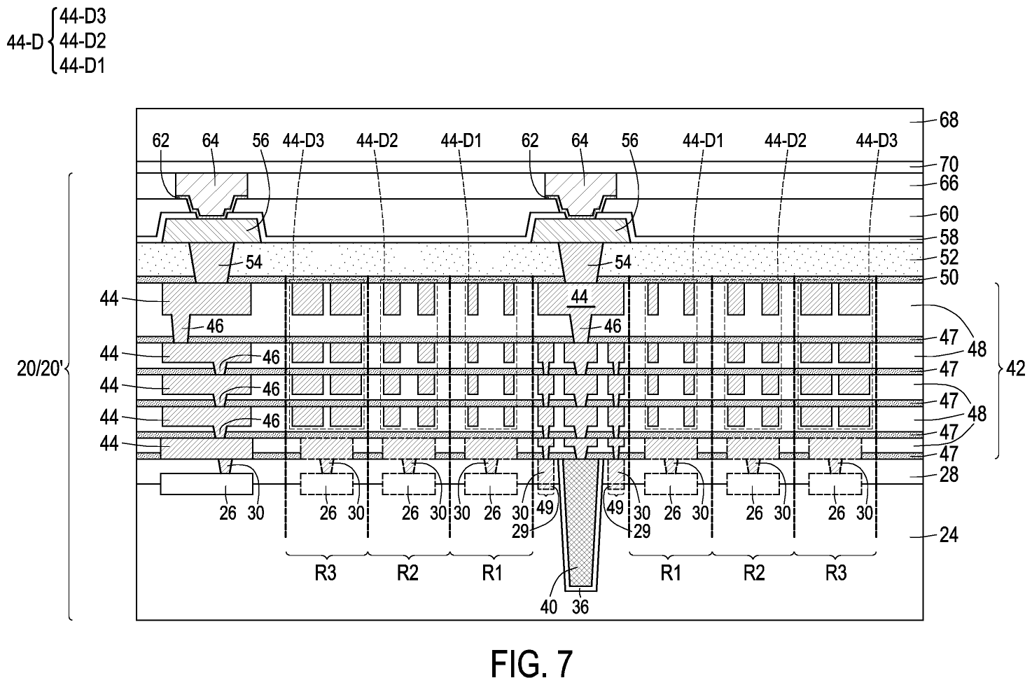

FIGS. 7 through 10 illustrate the process for forming backside features on the backside of semiconductor substrate 24. Referring to FIG. 7, carrier 68 (which may be a glass carrier) is attached to the front side of wafer 20. The attachment may be performed through an adhesive such as a light-to-heat-Conversion (LTHC) material 70, which is configured to be decomposed under the heat of light (such as a laser beam). The respective process is illustrated as process 216 in the process flow 200 as shown in FIG. 24.

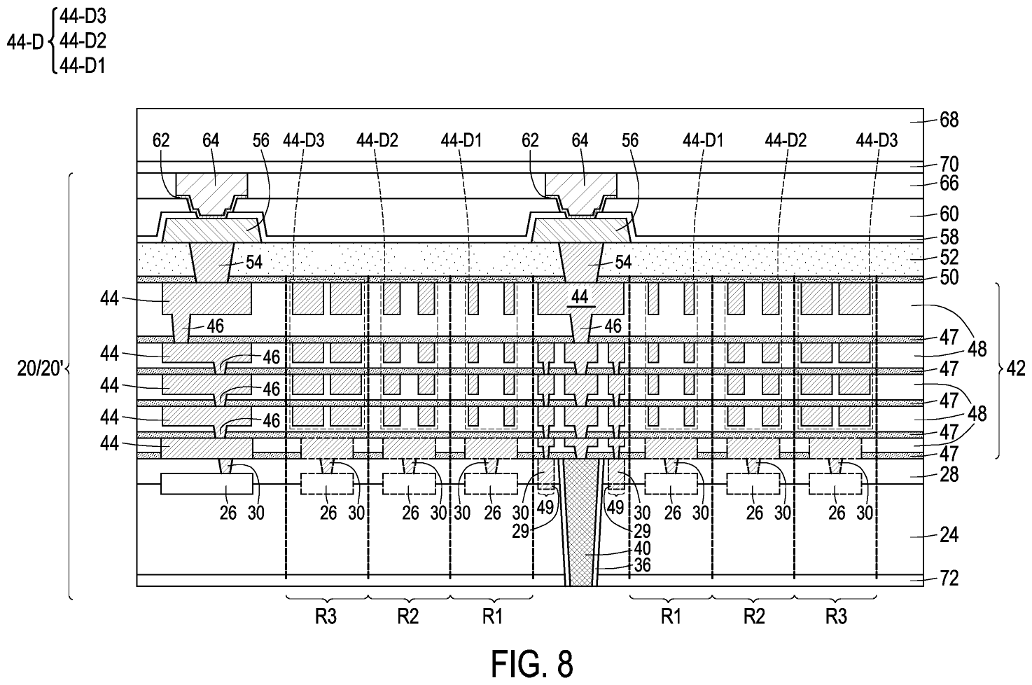

Referring to FIG. 8, a backside grinding process is performed to remove a portion of substrate 24, until TSV 40 is revealed. The respective process is illustrated as process 218 in the process flow 200 as shown in FIG. 24. Next, semiconductor substrate 24 is recessed slightly (for example, through etching), so that an end portion of TSV 40 protrudes out of the back surface of semiconductor substrate 24. Next, dielectric layer 72 is deposited, followed by a CMP process or a mechanical grinding process to re-expose TSV 40. TSV 40 thus penetrates through dielectric layer 72 also. In accordance with some embodiments, dielectric layer 72 is formed of silicon oxide, silicon nitride, or the like.

Referring to FIG. 9, backside interconnect structure 80 is formed. The respective process is illustrated as process 220 in the process flow 200 as shown in FIG. 24. Backside interconnect structure 80 includes one or more dielectric layers 76, and RDLs 74 in dielectric layers 76. RDLs 74 may include a pad portion contacting TSV 40. RDLs 74 may be formed of aluminum, copper, nickel, titanium, or the like in accordance with some embodiments. The formation of a layer of RDLs 74 may include forming a dielectric layer, etching the respective dielectric layer to form openings, plating a metal seed layer extending into the openings, forming a patterned plating mask, with some portions of the metal seed layer exposed, and plating to form the RDLs 74.

In accordance with some embodiments, at the time RDLs 74 are formed, dummy patterns 74-D1, 74-2, and 74-D3 (collectively referred to as dummy patterns 74-D hereinafter) are formed. Dummy patterns 74-D1, 74-2, and 74-D3 are formed in dummy pattern regions R1, R2, and R3, respectively, and may include portions in a plurality of RDL layers. The details of dummy patterns 74-D1, 74-2, and 74-D3 are discussed subsequently. Dummy patterns 74-D may be electrically floating.

In accordance with some embodiments, both of dummy patterns 74-D and 44-D are formed. In accordance with alternative embodiments, dummy patterns 44-D are formed, while dummy patterns 74-D are not formed. In accordance with yet alternative embodiments, dummy patterns 74-D are formed, while dummy patterns 44-D are not formed. Dummy patterns 74-D and 44-D may have the effect of correcting same type of warpage or opposite types of warpage. Accordingly, whether to form dummy patterns 74-D, dummy patterns 44-D, or both of dummy patterns 74-D and 44-D is determined by the likely warpage profile of device dies 20′ and wafer 20. The designing of dummy patterns 74-D and 44-D may include measuring (when wafer 20 is manufactured) and/or simulating the warpage profiles of device dies 20′ and wafer 20, adding dummy patterns 74-D and/or 44-D, and measuring and/or simulating the warpage profiles of device dies and wafers to select an optimum design of the dummy patterns from a plurality of designs.

Electrical connector 78 is also formed. In accordance with some embodiments, electrical connector 78 includes a solder region, which may be formed by plating a solder ball on the pad of RDL 74, and reflowing the solder ball. In accordance with alternative embodiments, electrical connector 78 is formed of non-reflowable (non-solder) metallic materials. For example, electrical connector 78 may be formed as a copper pad or pillar, and may or may not include a nickel capping layer.

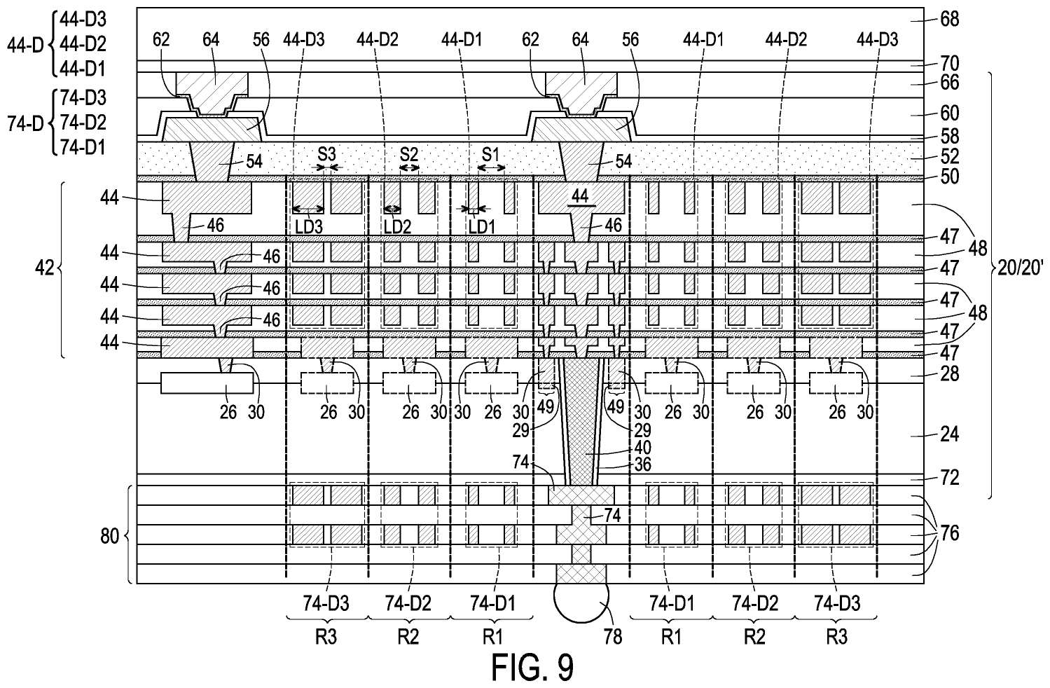

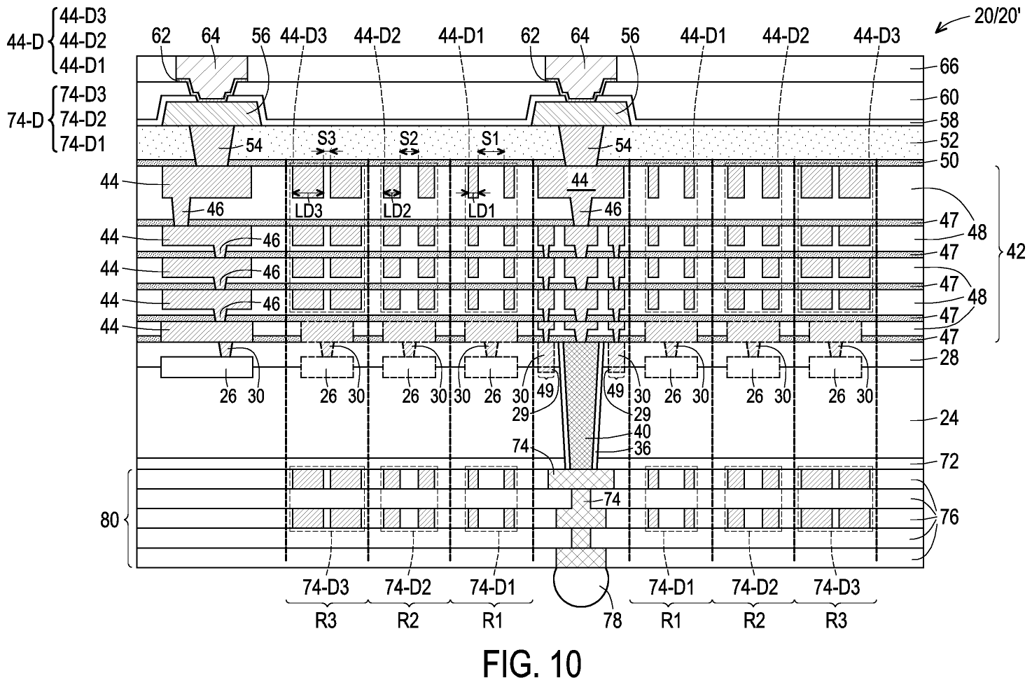

Carrier 68 is then de-bonded from the underlying wafer 20. The resulting structure is shown in FIG. 10. The respective process is illustrated as process 222 in the process flow 200 as shown in FIG. 24. Wafer 20 may then be singulated into a plurality of identical device dies 20′. The respective process is illustrated as process 224 in the process flow 200 as shown in FIG. 24.

The above-recited TSV formation process is referred to as a TSV-middle process since TSVs are formed after the formation of integrated circuit devices (FEOL structures), and before the formation of interconnect structures (BEOL structures). In accordance with alternative embodiments, TSVs may be formed using a TSV-first process (which is performed before the formation of the FEOL structures), or a TSV-last process (which is performed after the formation of the BEOL structures). The processes may also be realized through the discussion of the preceding embodiments.

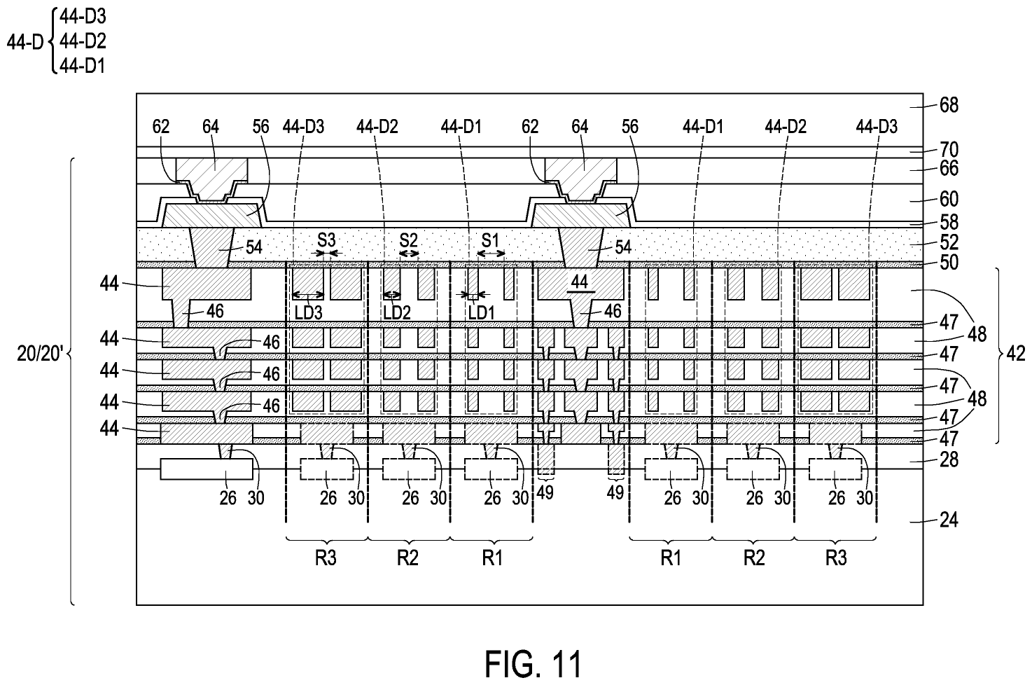

For example, FIGS. 11 through 14 illustrate a TSV-last process as an example. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

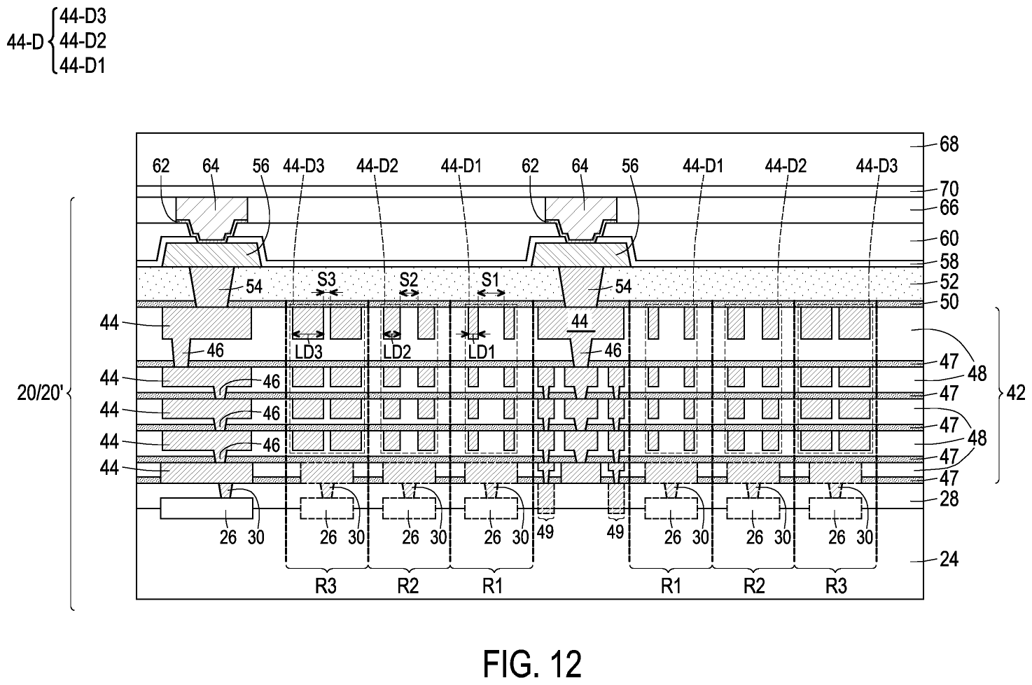

The initial steps of these embodiments are essentially the same as shown in FIGS. 1-7, and the resulting structure is essentially the same as shown in FIG. 7, except that TSV 40 and the corresponding dielectric liner 36 have not been formed yet. The corresponding structure is shown in FIG. 11. Next, as shown in FIG. 12, a backside thinning process is performed to thin semiconductor substrate 24.

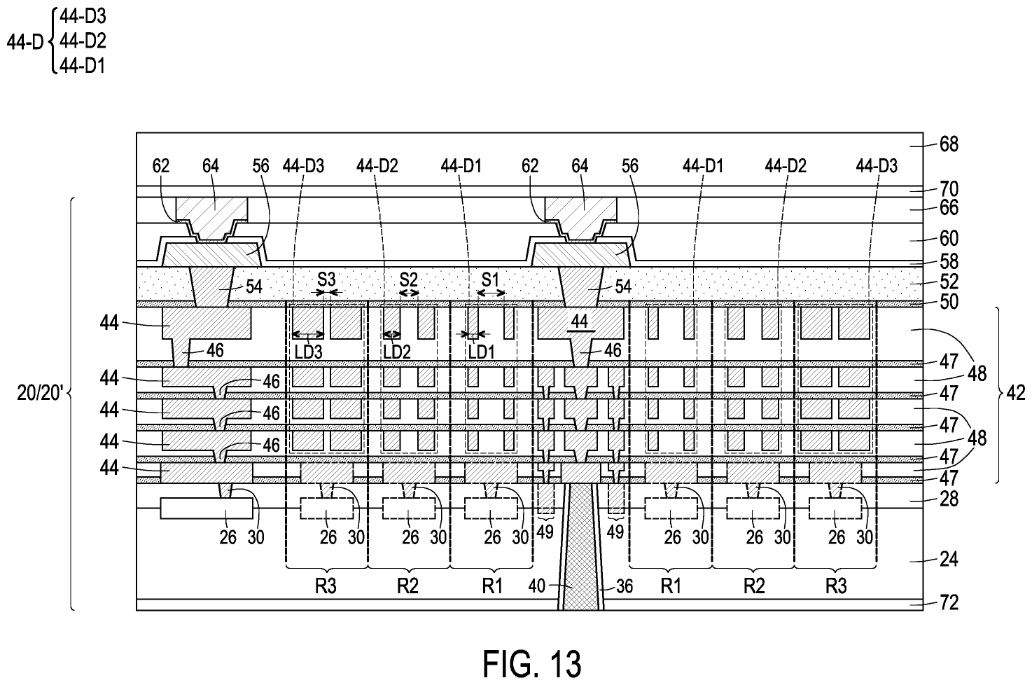

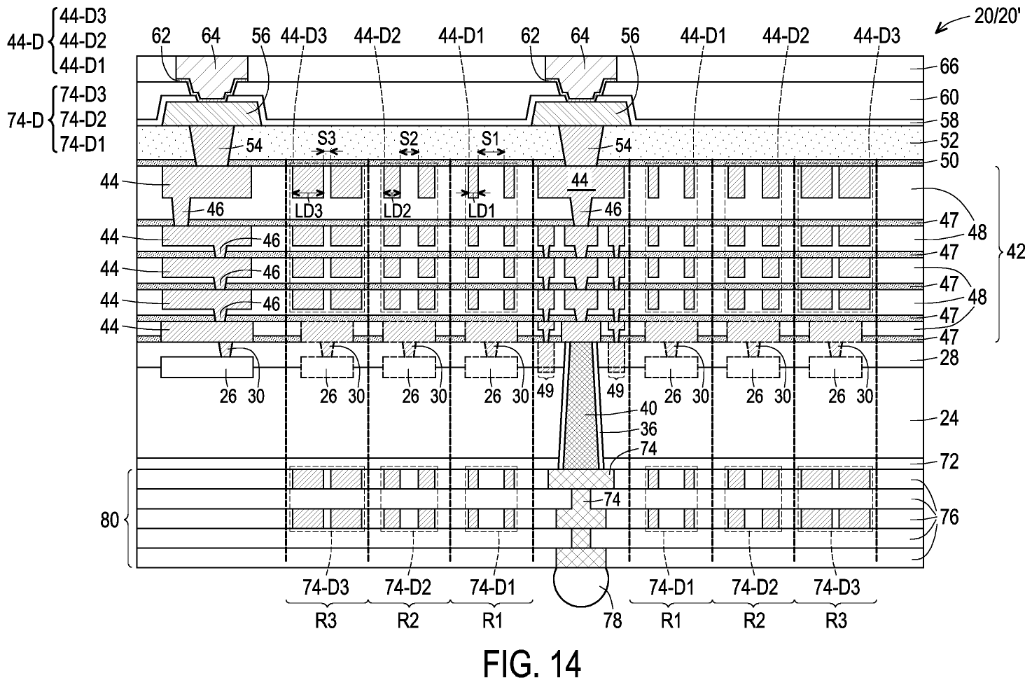

In a subsequent process, as also shown in FIG. 13, TSV 40 and dielectric liner 36 are formed from the backside of semiconductor substrate 24. The formation process may include etching semiconductor substrate 24 and a front-side dielectric layer(s) such as ILD 28 to reveal metal lines/pads 44, filling the openings with a dielectric liner and a conductive material, and performing a planarization process. FIG. 14 illustrates the formation of the backside interconnect structure 80 and electrical connector 78. A singulation process may then be performed to saw wafer 20 into discrete device dies 20′.

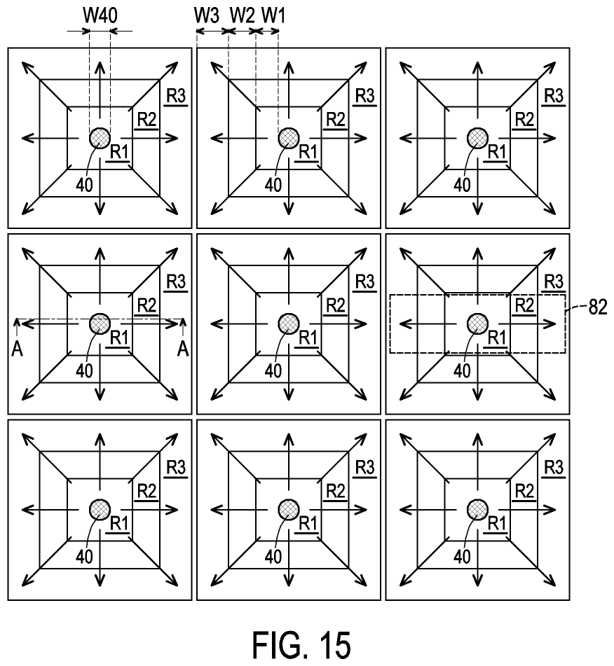

FIG. 15 illustrates a top view of TSVs 40 and the surrounding dummy pattern regions R1, R2, and R3, in which dummy patterns (44-D and 74-D as shown in FIGS. 10 and 14) are formed. Throughout the description, reference notation “44-D/74-D” represents dummy patterns 44-D and/or dummy patterns 74-D. TSVs 40 may be encircled by a plurality of dummy pattern regions such as R1, R2, and R3, or more, with outer regions encircling inner regions. Each of the dummy pattern regions R1, R2, and R3 has a pattern density PD, which may be uniform or substantially uniform (for example, with less than 20 percent variation) throughout the corresponding dummy pattern region. The dummy pattern regions R1, R2, and R3 have pattern density values PD1, PD2, and PD3, respectively.

Throughout the description, the pattern density of a metal layer refers to the ratio of the total area of all dummy patterns in a unit chip area (region), and in the same metal layer, to the total area of the unit chip area. Also, since the pattern density has large fluctuation when the unit chip area is too small, the unit chip area is defined as having both of a width and a length being greater than about 50× W40, with the value W40 being the length and the width (or diameter when TSV is round) of TSV 40. In accordance with some embodiments, the width W1 of dummy pattern region R1 may be in the range between about 100× W40 and about 500× W40. The width W2 of dummy pattern region R2 may be in the range between about 200× W40 and about 1,000× W40. The width W3 of dummy pattern region R3 may be in the range between about 100× W40 and about 1,000× W40.

In accordance with some embodiments, the pattern density values of the outer dummy pattern regions are greater than the pattern density values of the respective inner dummy pattern regions. The arrows shown in FIG. 15 represent the directions in which the pattern density of the dummy patterns 44-D/74-D increase. For example, pattern density PD3 of dummy pattern region R3 is greater than the pattern density PD2 of dummy pattern region R2, which is further greater than the pattern density PD1 of dummy pattern region R1.

In accordance with some embodiments, the pattern density PD1 of dummy pattern region R1 may be in the range between about 10% and about 30%. The pattern density PD2 of dummy pattern region R2 may be in the range between about 30% and about 50%. The pattern density PD3 of dummy pattern region R3 may be in the range between about 50% and about 70%. The differences (PD2-PD1) and (PD3-PD2) may be greater than about 10% or greater than about 20 percent.

In accordance with some embodiments, as illustrated in FIGS. 10, 14, 16, and 17, each of dummy pattern regions R1, R2, and R3 has a uniform pattern density or a substantially uniform pattern density, for example, with a fluctuation smaller than about 20 percent. The dummy pattern shapes and their sizes therein may be uniform or substantially uniform. In accordance with alternative embodiments, there is no clear boundary between dummy pattern regions R1, R2, and R3. Rather, in a direction from a first TSV to a middle line between the first TSV to a second TSV neighboring the first TSV, the pattern densities are increasingly greater. The dummy patterns 44-D/74-D may also be increasingly larger, and/or the spacings between neighboring dummy patterns 44-D/74-D may be increasingly smaller.

In accordance with some embodiments, as shown in FIG. 15, TSVs 40 may be arranged as an array. Accordingly, the dummy pattern regions R3 surrounding a plurality of TSVs 40 may be joined to form a grid pattern including a plurality of horizontal strips and a plurality of vertical strips, with the vertical strips and the horizontal strips having overlap regions. Also, the combined region of dummy patterns R2 and R3 may form a grid pattern including a plurality of horizontal strips and a plurality of vertical strips, with the vertical strips and the horizontal strips having overlap regions. In accordance with alternative embodiments, a plurality of TSVs 40 may form other patterns such as a hexagonal pattern, and the shapes of regions R1, R2, and R3 will change accordingly.

The TSV 40 and dummy patters 44-D and 74-D as shown in FIGS. 10 and 14 may be obtained from the cross-section A-A as shown in FIG. 15. Although not shown in FIGS. 10 and 14, it may be found from FIG. 15 that the region R3 of one TSV 40 may be joined with the region R3 of its neighboring TSV 40.

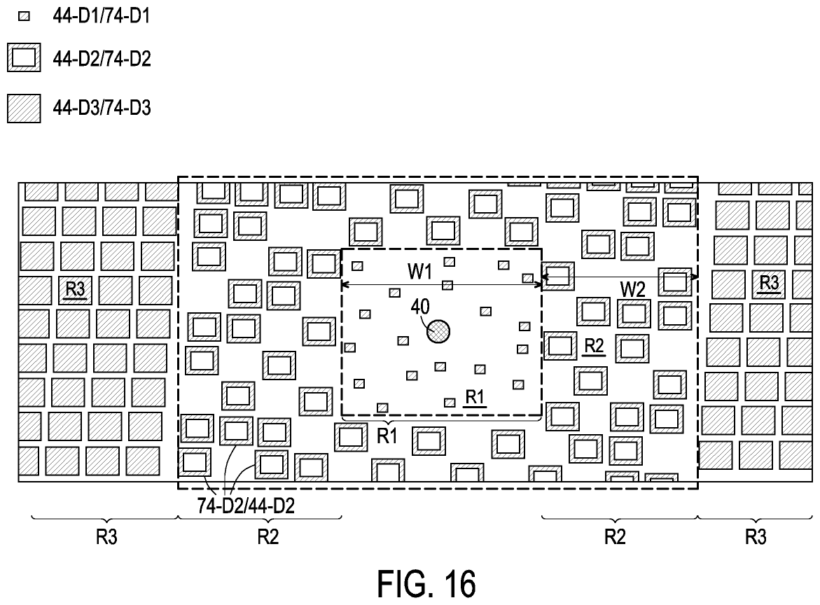

Referring to FIG. 10 or FIG. 14, the difference of pattern density values PD1, PD2, and PD3 may be achieved by making the spacings S1, S2, and S3 of dummy patterns 44-D1, 44-D2, and 44-D3, respectively as being different from each other, and/or the lateral dimensions LD1, LD2, and LD3 of dummy patterns 44-D1, 44-D2, and 44-D3, respectively as being different from each other. For example, spacing S3 may be smaller than spacing S2, and/or spacing S2 may be smaller than spacing S1. Lateral dimension L3 may be greater than lateral dimension L2, and/or dimension L2 may be greater than lateral dimension L1. Also, some of the patterns may be hollow (such as the dummy patterns 44-D1 in dummy pattern region R2 in FIG. 16) to reduce the pattern density. The difference of dummy patterns 74-D1, 74-D2, and 74-D4 may also be achieved similar to dummy patterns 44-D.

In accordance with some embodiments, the dummy patterns closer to TSVs have lower pattern densities than the dummy patterns farther away from the TSVs. In accordance with alternative embodiments, to meet different warpage situations, the dummy patterns farther away from the TSVs may have lower pattern densities than the dummy patterns closer to the TSVs.

FIG. 16 illustrates a top view of an example TSV 40 and its surrounding dummy pattern regions R1, R2, and R3 in accordance with some embodiments. It is appreciated that the patterns, the shapes, and the relative sizes of the illustrated dummy patterns are examples, and may not be up to scale. The illustrated region may be the sample region 82 in FIG. 15. In accordance with some embodiments, TSV 40 is encircled by dummy region R1 (as shown in FIG. 15), in which the dummy patterns 44-D1/74-D1 are located. Dummy patterns 44D1/74-D1 may have the smallest size and/or largest spacing among the dummy patterns in dummy regions R1, R2, and R3. Dummy patterns 44-D3/74-D3 may have the largest size and/or smallest spacing among the dummy patterns in dummy regions R1, R2, and R3. Dummy patterns 74-D2/44-D2 may be designed as being hollow to reduce the pattern density in dummy pattern region R2, or may be solid.

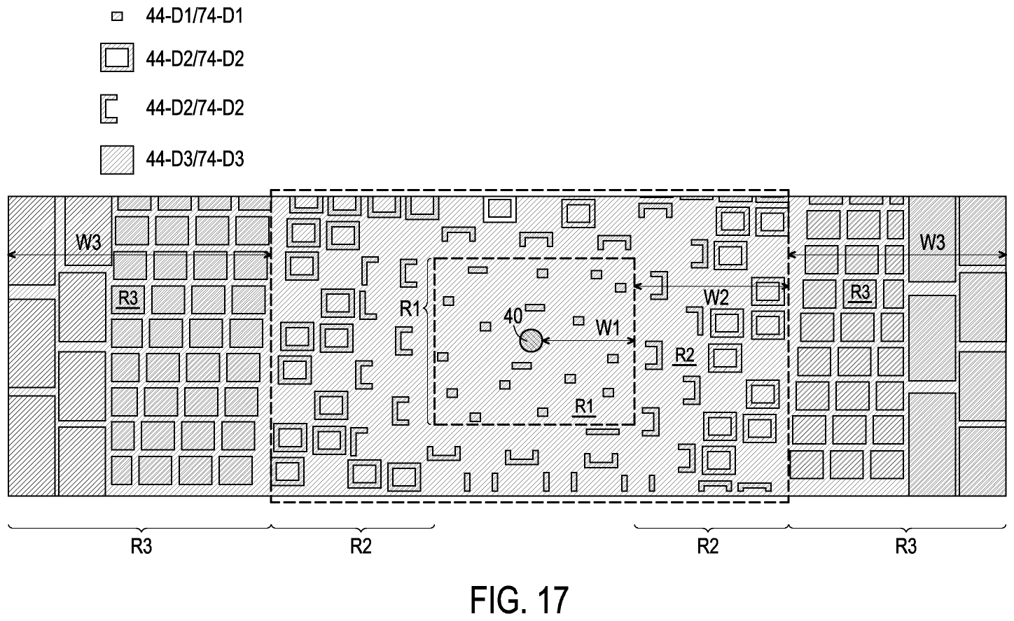

FIG. 17 illustrates a top view of an example TSV 40 and its surrounding region in accordance with alternative embodiments. In accordance with some embodiments, dummy pattern region R2 has different shapes of patterns. The inner portions have U-shaped dummy patterns (which are half ring-shaped patterns), and the outer portions have ring-shaped patterns (which are hollow). In accordance with some embodiments, dummy pattern region R3 have different types of patterns. The inner portions have square and smaller solid dummy patterns, and the outer portions have elongated and larger solid patterns. The embodiments in FIG. 17 may be considered as having 5 dummy pattern regions, or alternatively, the dummy pattern regions R2 and R3 are gradient.

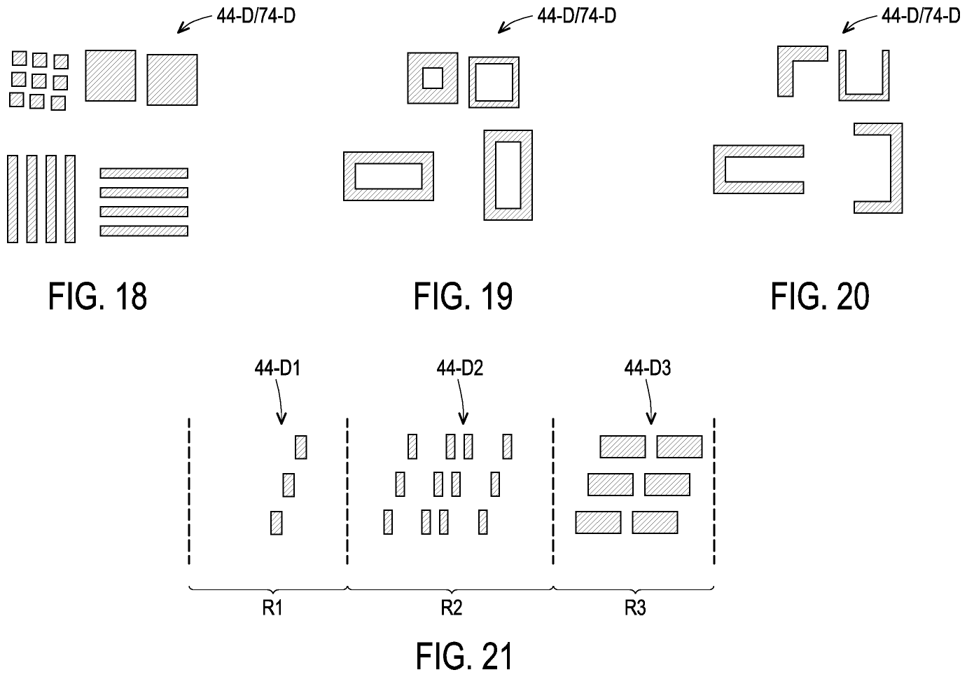

FIGS. 18, 19, and 20 illustrate different types of dummy patterns in accordance with some embodiments. FIG. 18 illustrates some candidate dummy patterns that are solid. These dummy patterns 44-D/74-D include small rectangles, large rectangles, vertical elongated strips, horizontal elongate strips, and the like. FIG. 19 illustrates the ring-shaped dummy patterns 44-D/74-D with different sizes and shapes. FIG. 20 illustrates the U-shaped or L-shaped dummy patterns 44-D/74-D with different sizes and shapes.

In accordance with some embodiments, the dummy patterns in different metal layers such as the top metal layer and an immediate underlying metal layer may be different, such as a having different shapes and/or sizes. In accordance with alternative embodiments, the dummy patterns in different metal layers such as the top metal layer and an immediate underlying metal layer may be the same, such as a having the same shapes and same sizes.

FIG. 21 illustrates some embodiments in which the dummy patterns in different metal layers such as the top metal layer and an immediate underlying metal layer may be staggered (offset and vertically misaligned), while the offset dummy patterns in different metal layers may have the same shape or different shapes and/or sizes.

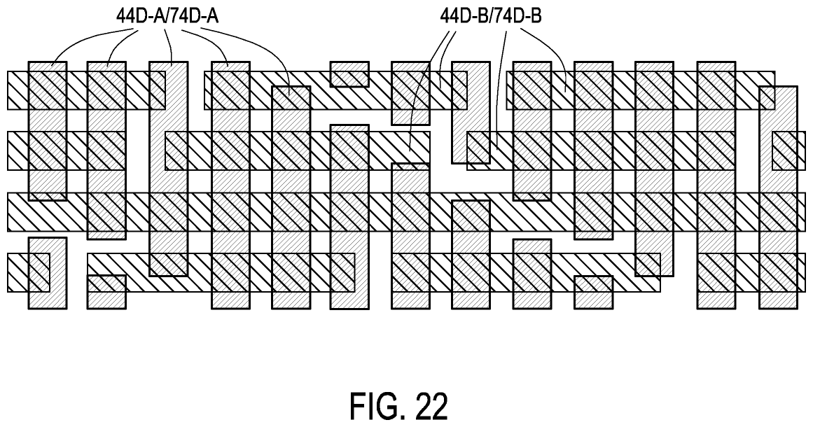

FIG. 22 illustrates some embodiments in which the dummy patterns in different metal layers such as the top metal layer and an immediate underlying metal layer are both elongated, with their lengthwise directions being perpendicular to each other. The dummy patterns 44D-A/74D-A in an upper metal layer and the dummy patterns 44D-B/74D-B in a lower metal layer are illustrated as examples.

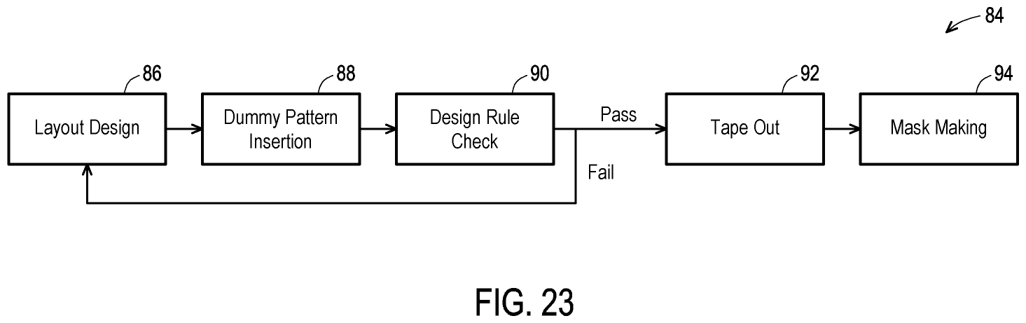

FIG. 23 illustrates a design flow 84 for designing the layout of the dummy patterns in accordance with some embodiments. The processes as shown in FIG. 23 are performed before the manufacturing of the dummy patterns and the TSVs on wafers. Referring to process 86, a layout design is provided. The layout that has been designed includes the layout of the different levels of the features of the wafer 20 (FIGS. 10 and 14), and also the layout of the TSVs. Dummy patterns 44-D and 74-D are then inserted in process 88 according to the rules that have been discussed. Next, as show in process 90, a design rule check is performed to ensure that the inserted dummy patterns do not violate design rules.

If the inserted dummy patterns pass the design rule check, then the layouts can be taped out (process 92). Lithography masks for manufacturing the wafer including the masks for forming the dummy patterns and TSVs are then made (process 94). If the inserted dummy patterns fail the design rule check, then the process loops back to process 88 to redesign the dummy patterns, followed by the design rule check again, the loop repeats until the dummy patterns may pass the design rule check.

Optionally, after the mask making, a sample wafer including the inserted dummy patterns may be made, and the warpages may be measured to determine whether the warpage profile meet design specification. If not, the process loops back to process 88 to repeat the above discussed process. Alternatively, after the design rule check and before the tape out, a simulation is performed to determine whether the warpage profile meet design specification. If not, the process loops back to process 88 to repeat the above discussed process.

The embodiments of the present disclosure have some advantageous features. By forming the dummy patterns with different pattern densities, the warpage of the respective device die and wafer may be reduced. The reduction of the warpage does not involve extra manufacturing cost.

In accordance with some embodiments, a method comprises forming an integrated circuit device on a semiconductor substrate; forming a first through-via penetrating through the semiconductor substrate; and forming dummy patterns surrounding the first through-via, wherein the dummy patterns comprise a first plurality of dummy patterns having a first pattern density; and a second plurality of dummy patterns, wherein the first plurality of dummy patterns are between the first through-via and the second plurality of dummy patterns, and wherein the second plurality of dummy patterns have a second pattern density different from the first pattern density.

In an embodiment, the dummy patterns further comprise a third plurality of dummy patterns, with the first plurality of dummy patterns and the second plurality of dummy patterns being between the first through-via and the third plurality of dummy patterns, wherein the third plurality of dummy patterns have a third pattern density different from both of the first pattern density and the second pattern density. In an embodiment, the third pattern density is greater than the second pattern density, and the second pattern density is greater than the first pattern density. In an embodiment, the forming the first through-via comprises forming the first through-via extending into the semiconductor substrate; performing a backside grinding process to reveal the first through-via from a backside of the semiconductor substrate; and forming a backside interconnect structure on the backside of the semiconductor substrate.

In an embodiment, the method further comprises forming additional dummy patterns on the backside of the semiconductor substrate, wherein the additional dummy patterns have a lower pattern density in a region closer to the first through-via, and a higher pattern density in a region farther away from the first through-via. In an embodiment, each of the first pattern density and the second pattern density is measured in chip areas with both of lengths and widths greater than about 50 μm. In an embodiment, the first through-via is formed through a via-middle process, and is formed after the integrated circuit device is formed, and before the dummy patterns are formed.

In an embodiment, the first through-via is formed through a via-last process, and is formed after both of the integrated circuit device and the dummy patterns are formed. In an embodiment, the method further comprises, when the first through-via is formed, forming a second through-via, wherein the dummy patterns further comprise a fourth plurality of dummy patterns having a fourth pattern density; a fifth plurality of dummy patterns having a fifth pattern density between the second through-via and the fourth plurality of dummy patterns; and a sixth plurality of dummy patterns having a sixth pattern density between the fifth plurality of dummy patterns and the second plurality of dummy patterns, wherein the fifth pattern density is greater than the fourth pattern density, and the sixth pattern density is greater than the fifth pattern density.

In an embodiment, the dummy patterns are electrically floating. In an embodiment, the first plurality of dummy patterns have different shapes than the second plurality of dummy patterns. In an embodiment, the first plurality of dummy patterns have different spacings than the second plurality of dummy patterns.

In accordance with some embodiments, a structure comprises a semiconductor substrate; a first interconnect structure overlying the semiconductor substrate; a second interconnect structure underlying the semiconductor substrate; a through-via penetrating through the semiconductor substrate, wherein the through-via electrically connects a first metal pad in the first interconnect structure to a second metal pad in the second interconnect structure; a first dummy pad region encircling the through-via, wherein the first dummy pad region comprises first dummy patterns having a first pattern density; and a second dummy pad region encircling the first dummy pad region, wherein the second dummy pad region comprises second dummy patterns having a second pattern density different from the first pattern density.

In an embodiment, the first dummy pad region has a substantially uniform pattern density of the first dummy patterns, and the second dummy pad region has a substantially uniform pattern density of the second dummy patterns. In an embodiment, the structure further comprises a third dummy pad region encircling the second dummy pad region, wherein the third dummy pad region comprises third dummy patterns having a third pattern density different from both of the first pattern density and the second pattern density.

In an embodiment, the structure further comprises devices at a top surface of the semiconductor substrate, wherein the first dummy patterns and the second dummy patterns are over the semiconductor substrate. In an embodiment, the structure further comprises active devices at a top surface of the semiconductor substrate, wherein the first dummy patterns and the second dummy patterns are under the semiconductor substrate.

In accordance with some embodiments, a structure comprises a semiconductor substrate; a first through-via and a second through-via penetrating through the semiconductor substrate; a redistribution structure comprising a plurality of dielectric layers over the semiconductor substrate; and a plurality of metal lines in the plurality of dielectric layers; and a plurality of dummy patterns in the plurality of dielectric layers, wherein in a top view of the structure, the plurality of dummy patterns are between the first through-via and the second through-via, wherein from regions closer to the first through-via or the second through-via to a middle region between the first through-via and the second through-via, pattern densities of the plurality of dummy patterns increase. In an embodiment, the middle region between the first through-via and the second through-via has a highest pattern density of dummy patterns. In an embodiment, the pattern densities of the plurality of dummy patterns are measured from device regions with length and width greater than about 50 μm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an integrated circuit device on a semiconductor substrate;
forming a first through-via penetrating through the semiconductor substrate; and
forming dummy patterns surrounding the first through-via, wherein the dummy patterns comprise:
a first plurality of dummy patterns having a first pattern density; and
a second plurality of dummy patterns, wherein the first plurality of dummy patterns are between the first through-via and the second plurality of dummy patterns, and wherein the second plurality of dummy patterns have a second pattern density different from the first pattern density.

2. The method of claim 1, wherein the dummy patterns further comprise a third plurality of dummy patterns, with the first plurality of dummy patterns and the second plurality of dummy patterns being between the first through-via and the third plurality of dummy patterns, wherein the third plurality of dummy patterns have a third pattern density different from both of the first pattern density and the second pattern density.

3. The method of claim 2, wherein the third pattern density is greater than the second pattern density, and the second pattern density is greater than the first pattern density.

4. The method of claim 1, wherein the forming the first through-via comprises:
forming the first through-via extending into the semiconductor substrate;
performing a backside grinding process to reveal the first through-via from a backside of the semiconductor substrate; and
forming a backside interconnect structure on the backside of the semiconductor substrate.

5. The method of claim 4 further comprising forming additional dummy patterns on the backside of the semiconductor substrate, wherein the additional dummy patterns have a lower pattern density in a region closer to the first through-via, and a higher pattern density in a region farther away from the first through-via.

6. The method of claim 1, wherein each of the first pattern density and the second pattern density is measured in chip areas with both of lengths and widths greater than about 50 μm.

7. The method of claim 1, wherein the first through-via is formed through a via-middle process, and is formed after the integrated circuit device is formed, and before the dummy patterns are formed.

8. The method of claim 1, wherein the first through-via is formed through a via-last process, and is formed after both of the integrated circuit device and the dummy patterns are formed.

9. The method of claim 1 further comprising, when the first through-via is formed, forming a second through-via, wherein the dummy patterns further comprise:
a fourth plurality of dummy patterns having a fourth pattern density;
a fifth plurality of dummy patterns having a fifth pattern density between the second through-via and the fourth plurality of dummy patterns; and
a sixth plurality of dummy patterns having a sixth pattern density between the fifth plurality of dummy patterns and the second plurality of dummy patterns, wherein the fifth pattern density is greater than the fourth pattern density, and the sixth pattern density is greater than the fifth pattern density.

10. The method of claim 1, wherein the dummy patterns are electrically floating.

11. The method of claim 1, wherein the first plurality of dummy patterns have different shapes than the second plurality of dummy patterns.

12. The method of claim 1, wherein the first plurality of dummy patterns have different spacings than the second plurality of dummy patterns.

13. A structure comprising:
a semiconductor substrate;
a first interconnect structure overlying the semiconductor substrate;
a second interconnect structure underlying the semiconductor substrate;
a through-via penetrating through the semiconductor substrate, wherein the through-via electrically connects a first metal pad in the first interconnect structure to a second metal pad in the second interconnect structure;
a first dummy pad region encircling the through-via, wherein the first dummy pad region comprises first dummy patterns having a first pattern density; and
a second dummy pad region encircling the first dummy pad region, wherein the second dummy pad region comprises second dummy patterns having a second pattern density different from the first pattern density.

14. The structure of claim 13, wherein the first dummy pad region has a substantially uniform pattern density of the first dummy patterns, and the second dummy pad region has a substantially uniform pattern density of the second dummy patterns.

15. The structure of claim 13 further comprising a third dummy pad region encircling the second dummy pad region, wherein the third dummy pad region comprises third dummy patterns having a third pattern density different from both of the first pattern density and the second pattern density.

16. The structure of claim 13 further comprising active devices at a top surface of the semiconductor substrate, wherein the first dummy patterns and the second dummy patterns are over the semiconductor substrate.

17. The structure of claim 13 further comprising active devices at a top surface of the semiconductor substrate, wherein the first dummy patterns and the second dummy patterns are under the semiconductor substrate.

18. A structure comprising:
a semiconductor substrate;
a first through-via and a second through-via penetrating through the semiconductor substrate;
a redistribution structure comprising:
a plurality of dielectric layers over the semiconductor substrate; and
a plurality of metal lines in the plurality of dielectric layers; and
a plurality of dummy patterns in the plurality of dielectric layers, wherein in a top view of the structure, the plurality of dummy patterns are between the first through-via and the second through-via, wherein from regions closer to the first through-via or the second through-via to a middle region between the first through-via and the second through-via, pattern densities of the plurality of dummy patterns increase.

19. The structure of claim 18, wherein the middle region between the first through-via and the second through-via has a highest pattern density of dummy patterns.

20. The structure of claim 18, wherein the pattern densities of the plurality of dummy patterns are measured from device regions with length and width greater than about 50 μm.
